(19) United States
(12) Patent Application Publication
(10) Pub. No.: US 2014/0235054 A1
(43) Pub. Date: Aug. 21, 2014

(54) TUNGSTEN DIAZABUTADIENE PRECURSORS, THEIR SYNTHESIS, AND THEIR USE FOR TUNGSTEN CONTAINING FILM DEPOSITIONS

(71) Applicant: L'Air Liquide, Société Änonyme pour I'Etude et I'Exploitation des Procédés Georges Glaude, Paris (FR)

(72) Inventors: Clément Lansalot-Matras, Seoul (KR); Nathanaelle Schneider, Ostwald (FR); Jullen Gatineau, Tsuchiura (JP)

(21) Appl. No.: 14/347,606

(22) PCT Filed: Sep. 27, 2012
(86) PCT No.: PCT/IB2012/055169

§ 371 Date: Mar. 26, 2014

Related U.S. Application Data
(60) Provisional application No. 61/539,765, filed on Sep. 27, 2011.

(51) Int. Cl. H01L 21/285

(52) U.S. Cl. CPC H01L 21/28556
USPC 438/681; 556/32

(57) ABSTRACT

Disclosed are tungsten diazabutadiene molecules, their method of manufacture, and their use in the deposition of tungsten-containing films. The disclosed molecules have the formula W(DAD)₃, wherein DAD is a 1,4-diazabuta-1,3-diene Isgand N4 and its reduced derivatives. The DAD !igand is directly coordinated to tungsten through the N atoms. The disclosed molecules may be used to deposit tungsten, tungsten-nitride, tungsten-carbonitride, or tungsten oxide films, or any other tungsten-containing films. The tungsten-containing films may be deposited using the disclosed molecules in thermal and/or plasma-enhanced CVD. ALD, pulse CVD or any other type of depositions methods.

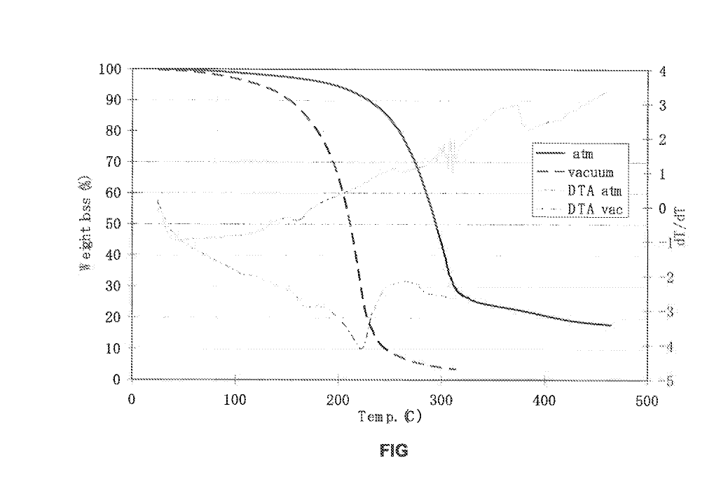

### CROSS REFERENCE TO RELATED APPLICATIONS

The present application claims the benefit of U.S. Provisional Application Ser. No. 61/539,765 filed Sep. 27, 2011, herein incorporated by reference in its entirety for all purposes.

### TECHNICAL FIELD

Disclosed are tungsten diazabutadiene molecules, their synthesis, and their use for the vapor deposition of tungsten containing films.

### BACKGROUND

Chemical vapor deposition (CVD) and atomic layer deposition (ALD) have been applied as techniques for depositing thin films for semiconductor devices because they enable the achievement of conformal films (metal, oxide, nitride, etc) through fine tuning of parameters during the process. The film growth is mainly controlled by the chemical reaction of metal-organic compounds (precursors), so the development of optimum precursors is essential under prediction of its property and reaction process. Precursors have been developed to reach required properties based on its specific application to certain types of film.

Several intrinsic properties of precursors should be considered before using them as molecules for CVD and ALD processes. First, liquid form and/or sufficient vapor pressure are necessary for easy delivery of the precursor in a gas phase into the reaction chamber from the containing vessel. Second, long term thermal stability in storage conditions and at delivery conditions is required. Thermal stability in the gas phase is also required to avoid impurities incorporation into the film. Third, strong reactivity toward reaction gases, such as ammonia or oxygen, is required for the precursor to be readily converted into the desired film on the sample substrate. Another important requirement of precursor to be considered at the step of precursor design is to control impurities in the film, which usually originate from the ligand during the deposition process.

Tungsten finds many different applications useful for the fabrication of nano-devices. Deposition of pure tungsten may be used to fill the holes that make contact to the transistor source and drain (“contact holes”) and also to fill vias between successive layers of metal. This approach is known as a “tungsten plug” process. The usage of tungsten may be developed due to the good properties of the films deposited using WF₆. However, it is necessary to provide an adhesion/barrier layer such as Ti/TiN to protect the underlying Si from attack by fluorine and to ensure adhesion of tungsten to the silicon dioxide.

Tungsten-silicide may be used on top of polysilicon gates to increase conductivity of the gate line and thus increase transistor speed. This approach is popular in DRAM fabrication, where the gate is also the word line for the circuit. WF₆ and SiH₄ may be used, but dichlorosilane (SiCl₂H₂) is more commonly employed as the silicon source, since it allows higher deposition temperatures and thus results in lower fluorine concentration in the deposited film.

Tungsten nitride (WNₓ) is considered to be a good barrier against diffusion of copper in microelectronics circuits. WNₓ may also be used in electrodes for thin-film capacitors and field-effect transistor.

The liquid and highly volatile +VI oxidation state of W in WF₆ allows for its use in the deposition of pure tungsten films in CVD mode using H₂ at high temperature (Applied Surface Science 73, 1993, 51-57; Applied Surface Science, 78, 2, 1994, 123-132). WF₆ may also be used in CVD mode in combination with silane for the production of tungsten silicide films at low temperature. (Y. Yamamoto et al. Proc. Int. Conf. on CVD—XIII (1996) 814; Surface Science 408 (1998) 190-194). Usage of WF₆ is however limited by the high thermal budget needed for the deposition of pure tungsten films and also by the presence of fluorine which may be responsible for etching of the underlying silicon surface.

The 0 oxidation state of W in W(CO)₆ allows for its use in the deposition of pure tungsten or tungsten nitride films in CVD mode. The high toxicity of the material has however limited its use in high volume manufacturing (Kaplan et al J. Electrochem. Soc. 1979, 117, 693; Sun et al Thin Solid Films 2001, 397, 109.)

W(CO)₂(1,3-butadiene)₂ may be used in CVD mode, but results in the deposition of tungsten carbide films (Jipa et al Chemical Vapor Deposition 2010 16 (7-9), 239).

The +IV oxidation state of W in bis cyclopentadienyl tungsten precursors having the formula W(RCp)₂H₂ may also allow its use in CVD mode for the deposition of pure tungsten, however high deposition temperatures are needed which results in high carbon contamination (Zinn et al Adv Mater. 1992, 375; Spee et al Mat. Scl. Eng 1993 (817) 108; Ogura et al J. of Vac. Sci. Tech. 2008, 26, 561).

U.S. Pat. No. 7,560,581B2 discloses the use of the bis-alkylimido bis-dialkylamino tungsten precursors for the production of tungsten nitride in ALD mode with or without plasma for copper barrier diffusion applications.

Aside from the above mentioned tungsten precursors, some diazabutadiene based molecules have been developed. Diazabutadiene (DAD) ligands are α-diimine ligands that may be used under different oxidation states.

U.S. Pat. No. 7,754,908 to Reuter et al. proposes the use of bis-alkylimido diazabutadiene tungsten precursors for the fabrication of tungsten containing films. The use of the alkylimido group may however provide drawbacks due to possible carbon incorporation in the resulting films. The tungsten molecules are not homoleptic and contain several kinds of ligands. Their synthesis is thus performed in several steps, adding complexity, handling and human resources to the synthesis, which finally impacts the cost of the molecule.

WO2012/027357 to Winter discloses methods of forming thin films on substrates including the step of contacting a surface with a precursor compound having a transition metal and one or more alkyl-1,3-diazabutadiene ligands.

Deposition of tungsten containing films (pure tungsten, tungsten nitride or tungsten silicide) in CVD or ALD mode remains challenging (high C, O, or F content in the film) due to the poor availability of suitable precursors. Therefore, a need remains for tungsten containing precursors suitable for CVD or ALD deposition processes. Desirable properties of the tungsten containing precursors for these applications are: i) liquid form or low melting point solid; ii) high volatility; iii) sufficient thermal stability to avoid decomposition during handling and delivery; iv) appropriate reactivity during CVD/ALD process; and v) oxygen-free for deposition of pure tungsten films in CVD or ALD (thermal or plasma mode) at temperatures lower than 200° C., and preferably lower than 150° C. At the same time, in order to allow the deposition at low temperature the thermal stability should not be too high.

### Notation and Nomenclature

Certain abbreviations, symbols, and terms are used throughout the following description and claims, and include:

As used herein, the indefinite article “a” or “an” means one or more.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “aryl group” refers to a ligand derived from an aromatic molecule, such as phenyl, benzyl, tolyl, o-xylol, etc.

As used herein, the abbreviation “Me” refers to a methyl group; the abbreviation “Et” refers to an ethyl group; the abbreviation “Pr” refers to a n-propyl group; the abbreviation “iPr” refers to an isopropyl group; the abbreviation “Bu” refers to butyl (n-butyl), the abbreviation “tBu” refers to a tert-butyl; the abbreviation “sBu” refers to a sec-butyl; the abbreviation “Cp” refers to cyclopentadienyl; the abbreviation “THF” refers to tetrahydrofuran; and the abbreviation “DME” refers to dimethoxy ethane.

The standard abbreviations of the elements from the periodic table of elements are used herein. It should be understood that elements may be referred to by these abbreviations (e.g., W refers to tungsten, Si refers to silicon, C refers to carbon, etc.).

As used herein, the abbreviation “DAD” refers to 1,4-diazabuta-1,3-diene ligand, an α-dilmine which has general structure of R₁—N═CR₃—CR₄═N—R₂, wherein each of R₁ to R₄ is independently selected from: H; C1-C6 linear, branched, or cyclic alkyl or aryl group; C1-C6 linear, branched, or cyclic alkylsilyl group (mono, bis, or tris alkyl); C1-C6 linear, branched, or cyclic alkylamino group such as NRR′, where R and R′ are independently selected from H or C1-C6 linear, branched, or cyclic alkyl or aryl group; C1-C6 linear, branched, or cyclic fluoroalkyl group (In which some or all of the substituents are F, i.e. partially or totally fluorinated); or an alkoxy substituent such as OR, wherein R is selected from H or a C1-C6 linear, branched, or cyclic alkyl or aryl group. As used herein “R-DAD” refers to the DAD ligand in which R₁ and R₂ are the “R” indicated and R₃ and R₄ are H (e.g., iPr-DAD is iPr-N═CH—CH═N-iPr).

The DAD ligand may be selected from one of three oxidation states, with each determining the bonding mode between the center element (M) and DAD ligands. X-ray fluorescence spectroscopy and/or X-ray crystal structure determination and/or magnetic moment determination may be used to determine oxidation state. For a better understanding, the generic structures of the DAD ligands are represented below with three different oxidation states: i) neutral, ii) mono-anionic, and iii) dianionic. One of ordinary skill in the art will recognize that the location of the double bonds in the diazabutadiene ligand changes based upon the oxidation state of the ligand, as shown below:

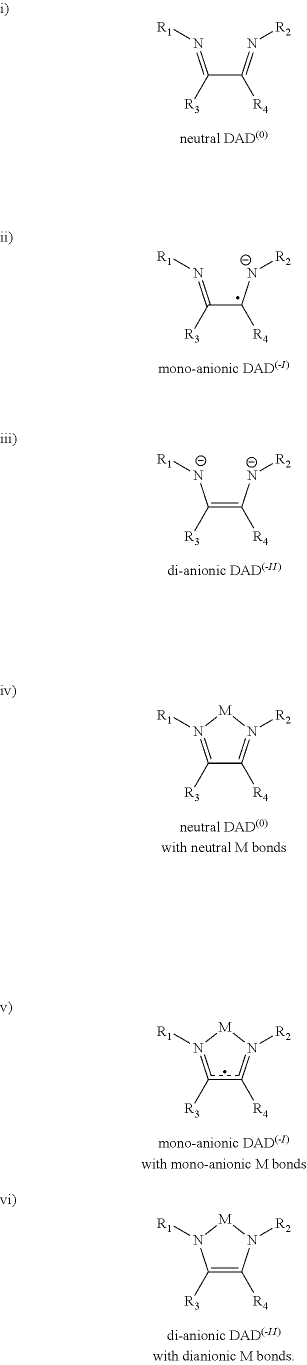

Even though written herein in linear form as R₁—N═CR₃—CR₄═N—R₂ (i.e., having two double bonds), the referenced DAD ligand may be neutral, mono-anionic, or di-anionic.

### SUMMARY

Tungsten diazabutadiene molecules having the formula W(R₁—N═CR₃—CR₄═N—R₂)₃ are disclosed, wherein each of R₁, R₂, R₃ and R₄ is independently selected from the group consisting of H; a C1-C6 linear, branched, or cyclic alkyl group; a C1-C6 linear, branched, or cyclic alkylsilyl group (mono, bis, or tris alkyl); a C1-C6 linear, branched, or cyclic alkylamino group such as NRR′, where R and R′ are independently selected from H or C1-C6 linear, branched, or cyclic alkyl or aryl group; a C1-C6 linear, branched, or cyclic fluoroalkyl group in which some or all of the substituents are F (i.e. partially or totally fluorinated alkyl group); and an alkoxy substituent such as OR, wherein R is selected from H or a C1-C6 linear, branched, or cyclic alkyl or aryl group. The disclosed molecules may further include one or more of the following aspects:
each of R₁, R₂, R₃ and R₄ being independently selected from the group consisting of H and a C1-C6 linear, branched, or cyclic alkyl group;
R₁ and R₂ being independently selected from the group consisting of Me, Et, nPr, iPr, nBu, tBu, and iBu;
R₃ and R₄ being independently selected from H or Me;
R₃ and R₄ being H;
R₁≠R₂;
R₁ and R₂ independently being iPr or nPr and R₃ and R₄ being H;
the molecule being W(nPrN═CH—CH=NnPr)₃; or
the molecule being W(iPrN═CH—CH=NiPr)₃.

Also disclosed are methods of depositing a tungsten containing film by introducing at least one tungsten diazabutadiene molecules disclosed above into a reactor having at least one substrate disposed therein and depositing at least part of the tungsten diazabutadiene molecule onto the at least one substrate to form the tungsten containing film. The disclosed methods may further include one or more of the following aspects:
the method being performed at a temperature between about 20° C. and about 600° C.;
the method being performed at a temperature between about 100° C. and about 400° C.;
the method being performed at a temperature between about 20° C. and about 150° C.;
the method being performed at a pressure between about 0.1 Pa and about 10⁵ Pa;
the method being performed at a pressure between about 2.5 Pa and about 10³ Pa;
the method being selected from the group consisting of chemical vapor deposition (CVD), atomic layer deposition (ALD), plasma CVD, plasma ALD, pulse CVD, low pressure CVD, sub-atmospheric CVD, atmospheric pressure CVD, hot-wire CVD, hot-wire ALD, and super critical fluid deposition;
the method being thermal atomic layer deposition (ALD);
the tungsten containing film being selected from the group consisting of tungsten (W), tungsten silicide (WSi), tungsten nitride (WN), tungsten carbide (WC), tungsten carbonitride (WNC), and tungsten oxide (WO);
introducing a reaction gas into the reactor at the same time or at an alternate time as the introduction of the tungsten diazabutadiene molecule;
the reaction gas being a reducing agent;
the reducing agent being selected from the group consisting of: N₂, H₂; SiH₄; Si₂H₆; Si₃H₈; NH₃; (CH₃)₂SiH₂; (C₂H₅)₂SiH₂; (CH₃)SiH₃; (C₂H₅)SiH₃; phenyl silane; N₂H₄; N(SiH₃)₃; N(CH₃)H₂; N(C₂H₅)H₂; N(CH₃)₂H; N(C₂H₅)₂H; N(CH₃)₃; N(C₂H₅)₃; (SiMe₃)₂NH; (CH₃)HNNH₂; (CH₃)₂NNH₂; phenyl hydrazine; B₂H₆; 9-borabicyclo[3,3,1]nonane; dihydrobenzenfuran; pyrazoline; trimethylaluminium; dimethylzinc; diethylzinc; radical species thereof; and mixtures thereof,
the reaction gas being an oxidizing agent; and
the oxidizing agent being selected from the group consisting of: O₂; O₃; H₂O; H₂O₂; NO; NO₂; carboxylic acids; radical species thereof; and mixtures thereof.

### BRIEF DESCRIPTION OF THE FIGURE

For a further understanding of the nature and objects of the present invention, reference should be made to the following detailed description, taken in conjunction with the accompanying drawing, wherein:

FIGURE is a graph showing the atmospheric and vacuum thermogravimetric analysis of W(iPrN-CH═CH—NiPr)₃.

### DETAILED DESCRIPTION OF PREFERRED EMBODIMENTS

Disclosed are diazabutadiene tungsten compounds having the formula W(R₁—N═CR₃—CR₄═N—R₂)₃, wherein each of R₁, R₂, R₃ and R₄ is independently selected from the group consisting of H; a C1-C6 linear, branched, or cyclic alkyl group; a C1-C6 linear, branched, or cyclic alkylsilyl group (mono, bis, or tris alkyl); a C1-C6 linear, branched, or cyclic alkylamino group such as NRR′, where R and R′ are independently selected from H or C1-C6 linear, branched, or cyclic alkyl or aryl group; a C1-C6 linear, branched, or cyclic fluoroalkyl group in which some or all of the substituents are F (i.e. partially or totally fluorinated alkyl group); and an alkoxy substituent such as OR, wherein R is selected from H or a C1-C6 linear, branched, or cyclic alkyl or aryl group. In some embodiments, each of R₁, R₂, R₃ and R₄ is independently selected from the group consisting of H and a C1-C6 linear, branched, or cyclic alkyl group. In some embodiments, R₁ and R₂ are independently selected from the group consisting of Me, Et, nPr, iPr, nBu, tBu, and iBu. In some embodiments, R₃ and R₄ are independently selected from H or Me. In some embodiments R₁ and R₂ are iPr or nPr and R₃ and R₄ are H. In some embodiments, R₁≠R₂.

The physical and thermal properties of the compounds vary depending upon the R substituents utilized. In some embodiments, the disclosed tungsten diazabutadiene compounds are homoleptic, permitting synthesis in one step, which enables a lower synthesis cost. In other embodiments, the disclosed tungsten diazabutadiene compounds are asymmetric, which may yield compounds having better volatility and melting point.

The sole presence of the W—N bonds in the tungsten diazabutadlene compounds limits the intrusion of other elements, such as carbon, into the resulting tungsten-containing films. The flexibility of the W—N bond in terms of film deposition also allows using the molecules for tungsten, tungsten-nitride, tungsten-carbonitride, tungsten oxide or any other type of tungsten-containing films. These compounds may allow for tungsten containing film deposition at lower temperatures due to the adequate thermal stability of the compound. As the compounds are oxygen-free, deposition of pure tungsten films in CVD or ALD (thermal or plasma mode) may occur at temperatures lower than 200° C., preferably lower than 150° C. The compounds may be used for deposition of films with controlled thickness and composition at targeted temperatures.

Exemplary tungsten-containing compounds include without limitation: W(MeN═CH—CH═NMe)₃, W(EtN═CH—CH═NEt)₃, W(nPrN═CH—CH=NnPr)₃, W(iPrN═CH—CH=NiPr)₃, W(nBuN═CH—CH=NnBu)₃, W(tBuN═CH—CH=NtBu)₃, W(iBuN═CH—CH═NiBu)₃, W(nPrN═CH—CH=NiPr)₃, W(nPrN═CH—CH=NtBu)₃, W(iPrN═CH—CH=NtBu)₃, W(MeN═CMe-CH═NMe)₃, W(EtN═CMe-CH═NEt)₃, W(nPrN═CMe-CH=NnPr)₃, W(iPrN═CMe-CH=NiPr)₃, W(nBuN═CMe-CH=NnBu)₃, W(tBuN═CMe-CH=NtBu)₃, W(iBuN═CMe-CH=NiBu)₃, W(iPrN═CMe-CH═NMe)₃, W(iPrN═CMe-CH═NEt)₃, W(iPrN═CMe-CH=NtBu)₃, W(MeN═CMe-CMe=NMe)₃, W(EtN═CMe-CMe=NEt)₃, W(nPrN═CMe-CMe=NnPr)₃, W(iPrN═CMe-CMe—NiPr)₃, W(nBuN═CMe-CMe=NnBu)₃, W(tBuN═CMe-CMe=NtBu)₃, W(iBuN═CMe-CMe=NiBu)₃, W(MeN═CMe-CMe=NEt)₃, W(MeN═CMe-CMe=NiPr)₃, W(EtN═CMe-CMe=NiPr)₃, W(MeN═C(CF₃)—CH═NMe)₃, W(EtN═C(CF₃)—CH═NEt)₃, W(nPrN═C(CF₃)—CH=NnPr)₃, W(iPrN═C(CF₃)—CH═NiPr)₃, W(nBuN═C(CF₃)—CH=NnBu)₃, W(tBuN═C(CF₃)—CH=NtBu)₃, W(iBuN═C(CF₃)—CH=NiBu)₃, W(MeN═C(CF₃)—C(CF₃)═NMe)₃, W(EtN═C(CF₃)—C(CF₃)═NEt)₃, W(nPrN═C(CF₃)—C(CF₃)=NnPr)₃, W(iPrN═C(CF₃)—C(CF₃)=NiPr)₃, W(nBuN═C(CF₃)—C(CF₃)=NnBu)₃, W(tBuN═C(CF₃)—C(CF₃)=NtBu)₃, W(iBuN═C(CF₃)—C(CF₃)═NiBu)₃, W(nPrN═CH—CH═NiPr)₃, W(iPrN═CH—CH=NtBu)₃, W(nPrN═CH—CH=NtBu)₃, W(nPrN═CMe-CH=NiPr)₃, W(iPrN═CMe-CH=NtBu)₃, W(nPrN═CMe-CH=NtBu)₃, W(nPrN═CMe-CMe=NiPr)₃, W(iPrN-CMe-CMe=NtBu)₃ and W(nPrN═CMe-CMe=NtBu)₃.

Preferably the tungsten-containing compound is W(iPrN═CH—CH═NiPr)₃ or W(nPrN═CH—CH=NnPr)₃.

The tungsten containing compound may be synthesized by reducing in a first step WCl₄ or WCl₆ with a reductant selected from but without limitation Na, Na/naphthalene, Li, or Zn in a solvent selected from but without limitation THF or DME, and in a second step reacting the product of the first step with three equivalents of the corresponding neutral diazabutadiene ligand. Except for the diazabutadiene ligands, all of the reactants are commercially available.

Alternatively, the tungsten-containing precursor may be synthesized in two steps by reacting WCl₄ in a first or second step with one equivalent of neutral diazabutadiene and in a first or second step with two equivalents of bis lithiated diazabutadiene, as depicted below. Sodium or potassium may be used to reduce the diazabutadiene. The bis lithiated diazabutadiene may be prepared beforehand by reacting diazabutadiene with lithium metal. Except for the diazabutadiene ligands, all of the other reactants are commercially available.

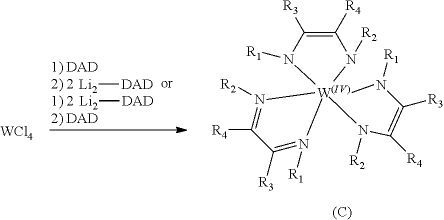

In another alternative, the tungsten-containing precursor may be synthesized by reacting WCl₆ with three or more equivalents of bis lithiated diazabutadiene, as depicted below. More synthesis details are provided in the Examples that follow. Bis lithiated diazabutadlene may be prepared beforehand by reacting diazabutadiene with lithium metal. Sodium or potassium may also be used to reduce the diazabutadiene. Except for the diazabutadiene ligands, all of the other reactants are commercially available.

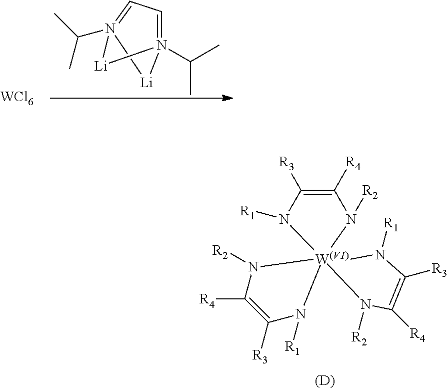

Diazabutadiene ligands are prepared according the method published in H. Tom Dieck Z. Naturforsch. 36b, 814-822, 1981, which is incorporated herein in its entirety by reference. More particularly, the diazabutadiene ligand may be synthesized by reacting one molar equivalent of the relevant glyoxal (O═CH—CH═O, O═CH-CMe=O, O═C(CF₃)CH═O, etc) with two or more molar equivalents of an amine (RNH₂) to produce the relevant diazabutadiene (RN═CH—CH═NR, RN═CH-CMe=NR, RN═C(CF₃)CH═NR, etc.). For asymmetric ligands, Applicants believe that one molar equivalent of the first amine (RNH₂) may be utilized to produce an intermediate (RN═CH—CH═O, RN═CH-CMe=O, RN═C(CF₃)CH═O, etc), which may be reacted with one or more molar equivalents of a second amine (R′NH₂) to produce the asymmetric diazabutadiene (RN═CH—CH═NR′, RN═CH-CMe=NR′, RN═C(CF₃)CH═NR′, etc).

Also disclosed are methods for forming a tungsten-containing layer on a substrate using a vapor deposition process. The method may be useful in the manufacture of semiconductor, photovoltaic, LCD-TFT, or flat panel type devices.

The tungsten containing film may be deposited by introducing at least one of the disclosed tungsten diazabutadiene compounds discussed above into a reactor having at least one substrate disposed therein. At least part of the disclosed tungsten diazabutadiene compound is deposited onto the at least one substrate to form the tungsten containing film.

The disclosed tungsten diazabutadlene compounds may be used to deposit thin tungsten-containing films using any deposition methods known to those of skill in the art. Examples of suitable deposition methods include without limitation, conventional chemical vapor deposition (CVD) or atomic layer deposition (ALD), or other types of deposition that are related to vapor coating, using techniques such as plasma [plasma enhanced chemical vapor deposition (PECVD) or plasma enhanced atomic layer deposition (PEALD)], tuned introduction schemes [pulsed chemical vapor deposition (PCVD)], tuned reaction pressure [low pressure chemical vapor deposition (LPCVD), subatmospheric CVD (SACVD), or atmospheric pressure CVD (APCVD)], hot-wire chemical vapor deposition (HWCVD, also known as catCVD, in which a hot wire serves as a catalyst for the deposition process), hot-wire atomic layer deposition (HWALD), or super critical fluid incorporated deposition, or combinations thereof. In one alternative, a thermal CVD deposition is preferred, particularly when fast growth, conformality, process-orientation and one direction films are required. In another alternative, a thermal ALD deposition process is preferred, particularly when superior conformality of films deposited on challenging surfaces (e.g., trenchs, holes, vias) is required.

The disclosed tungsten diazabutadiene compounds may be supplied either in neat form or in a blend with a suitable solvent, such as ethyl benzene, xylene, mesitylene, decane, dodecane. The disclosed compounds may be present in varying concentrations in the solvent.

One or more of the neat tungsten diazabutadiene compounds or blends are introduced into a reactor in vapor form by conventional means, such as tubing and/or flow meters. The vapor form may be produced by vaporizing the neat compound or blend through a conventional vaporization step such as direct vaporization, distillation, or by bubbling, or by using a sublimator such as the one disclosed in PCT Publication WO2009/087609 to Xu et al. The neat compound or blend may be fed in liquid state to a vaporizer where it is vaporized before it is introduced into the reactor. Alternatively, the neat compound or blend may be vaporized by passing a carrier gas into a container containing the neat compound or blend or by bubbling the carrier gas into the neat compound or blend. The carrier gas may include, but is not limited to, Ar, He, N₂, and mixtures thereof. Bubbling with a carrier gas may also remove any dissolved oxygen present in the neat compound or blend. The carrier gas and compound are then introduced into the reactor as a vapor.

If necessary, the container of disclosed compound or blend may be heated to a temperature that permits the compound/blend to be in its liquid phase and/or to have a sufficient vapor pressure. The container may be maintained at temperatures in the range of, for example, approximately 0° C. to approximately 150° C. Those skilled in the art recognize that the temperature of the container may be adjusted in a known manner to control the amount of compound vaporized.

The reactor may be any enclosure or chamber within a device in which deposition methods take place such as without limitation, a parallel-plate type reactor, a cold-wall type reactor, a hot-wall type reactor, a single-wafer reactor, a multi-wafer reactor, or other types of deposition systems under conditions suitable to cause the precursors to react and form the layers.

Generally, the reactor contains one or more substrates onto which the thin films will be deposited. The one or more substrates may be any suitable substrate used in semiconductor, photovoltaic, flat panel, or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium, or gold) may be used. The substrate may also have one or more layers of differing materials already deposited upon it from a previous manufacturing step.

The temperature and the pressure within the reactor are held at conditions suitable for vapor deposition of at least part of the tungsten diazabutadlene compound onto the substrate. In other words, after introduction of the vaporized compound into the chamber, conditions within the chamber are such that at least part of the vaporized compound is deposited onto the substrate to form a tungsten-containing film. For instance, the pressure in the reactor may be held between about 0.1 Pa and about 10⁵ Pa, more preferably between about 2.5 Pa and about 10³ Pa, as required per the deposition parameters. Likewise, the temperature in the reactor may be held between about 20° C. and about 600° C., preferably between about 100° C. and about 400° C. or between about 20° C. and about 150° C.

The temperature of the reactor may be controlled by controlling the temperature of the substrate holder and/or controlling the temperature of the reactor wall. Devices used to heat the substrate are known in the art. The reactor wall may be heated to a sufficient temperature to obtain the desired film at a sufficient growth rate and with desired physical state and composition. A non-limiting exemplary temperature range to which the reactor wall may be heated includes from approximately 20° C. to approximately 600° C. When a plasma deposition process is utilized, the deposition temperature may range from approximately 20° C. to approximately 350° C. Alternatively, when a thermal process is performed, the deposition temperature may range from approximately 200° C. to approximately 600° C.

In addition to the disclosed tungsten diazabutadlene compounds, a reaction gas may also be introduced into the reactor. The reaction gas may be an oxidizing agent such as one of O₂; O₃; H₂O; H₂O₂; oxygen containing radicals such as O. or OH.; NO; NO₂; carboxylic acids such as formic acid, acetic acid, propionic acid; radical species of NO, NO₂, or the carboxylic acids; and mixtures thereof. Preferably, the oxidizing agent is selected from the group consisting of O₂, O₃, H₂O, H₂O₂, oxygen containing radicals thereof such as O. or OH., and mixtures thereof. Alternatively, the reaction gas may be a reducing agent such as one of H₂, NH₃, SiH₄, Si₂H₆, Si₃H₈, (CH₃)₂SiH₂, (C₂H₅)₂SiH₂, (CH₃)SiH₃, (C₂H₅)SiH₃, phenyl silane, N₂H₄, N(SiH₃)₃, N(CH₃)H₂, N(C₂H₅)H₂, N(CH₃)₂H, N(C₂H₅)₂H, N(CH₃)₃, N(C₂H₅)₃, (SiMe₃)₂NH, (CH₃)HNNH₂, (CH₃)₂NNH₂, phenyl hydrazine, N-containing molecules, B₂H₆, 9-borabicyclo[3,3,1]nonane, dihydrobenzenfuran, pyrazoline, trimethylaluminium, dimethylzinc, diethylzinc, radical species thereof, and mixtures thereof. Preferably, the reducing agent is H₂, NH₃, SiH₄, Si₂H₆, Si₃H₆, SiH₂Me₂, SiH₂Et₂, N(SiH₃)₃, hydrogen radicals thereof, or mixtures thereof.

The reaction gas may be treated by a plasma, in order to decompose the reaction gas into its radical form. N₂ may also be utilized as a reducing agent when treated with plasma. For instance, the plasma may be generated with a power ranging from about 50 W to about 500 W, preferably from about 100 W to about 200 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

The vapor deposition conditions within the chamber allow the tungsten diazabutadiene compounds and/or the reaction gas to form a tungsten-containing film on the substrate. In some embodiments, Applicants believe that plasma-treating the reaction gas may provide the reaction gas with the energy needed to react with the disclosed compounds.

Depending on what type of film is desired to be deposited, a second precursor may be introduced into the reactor. The second precursor comprises another element source, such as silicon, copper, praseodymium, manganese, ruthenium, titanium, tantalum, bismuth, zirconium, hafnium, lead, niobium, magnesium, aluminum, lanthanum, or mixtures of these. When a second precursor is utilized, the resultant film deposited on the substrate may contain at least two different elements.

The tungsten diazabutadiene compounds and reaction gases may be introduced into the reactor either simultaneously (chemical vapor deposition), sequentially (atomic layer deposition), or different combinations thereof. The reactor may be purged with an inert gas between the introduction of the compound and the introduction of the reaction gas. Alternatively, the reaction gas and the compound may be mixed together to form a reaction gas/compound mixture, and then introduced to the reactor in mixture form. Another example is to introduce the reaction gas continuously and to introduce the at least one tungsten diazabutadiene compound by pulse (pulsed chemical vapor deposition).

The vaporized compound and the reaction gas may be pulsed sequentially or simultaneously (e.g. pulsed CVD) into the reactor. Each compound pulse may last for a time period ranging from about 0.01 seconds to about 10 seconds, alternatively from about 0.3 seconds to about 3 seconds, alternatively from about 0.5 seconds to about 2 seconds. In another embodiment, the reaction gas may also be pulsed into the reactor. In such embodiments, the pulse of each gas may last for a time period ranging from about 0.01 seconds to about 10 seconds, alternatively from about 0.3 seconds to about 3 seconds, alternatively from about 0.5 seconds to about 2 seconds.

Depending on the particular process parameters, deposition may take place for a varying length of time. Generally, deposition may be allowed to continue as long as desired or necessary to produce a film with the necessary properties. Typical film thicknesses may vary from several angstroms to several hundreds of microns, depending on the specific deposition process. The deposition process may also be performed as many times as necessary to obtain the desired film.

In one non-limiting exemplary CVD type process, the vapor phase of the disclosed tungsten diazabutadiene compound and a reaction gas are simultaneously introduced into the reactor. The two react to deposit at least part of the tungsten diazabutadiene compound on the substrate as the resulting tungsten-containing thin film. When the reaction gas in this exemplary CVD process is treated with a plasma, the exemplary CVD process becomes an exemplary PECVD process. The reaction gas may be treated with plasma prior or subsequent to introduction into the chamber.

In one non-limiting exemplary ALD type process, the vapor phase of the disclosed tungsten diazabutadiene compound is introduced into the reactor, where conditions are suitable for the compound to react with a substrate. Excess compound may then be removed from the reactor by purging and/or evacuating the reactor. A reducing agent (for example, H₂) is introduced into the reactor where it reacts with the deposited compound in a self-limiting manner. Any excess reducing agent is removed from the reactor by purging and/or evacuating the reactor. If the desired film is a tungsten film, this two-step process may provide the desired film thickness or may be repeated until a film having the necessary thickness has been obtained.

Alternatively, if the desired film is contains two elements, the two-step process above may be followed by introduction of the vapor of a second precursor into the reactor. The second precursor will be selected based on the desired second element in the film being deposited. The second precursor is introduced into the reactor, where conditions are suitable for the second precursor to react with the deposited tungsten layer. Any excess second precursor is removed from the reactor by purging and/or evacuating the reactor. Once again, a reducing agent may be introduced into the reactor to react with the deposited second precursor. Excess reducing agent is removed from the reactor by purging and/or evacuating the reactor. If a desired film thickness has been achieved, the process may be terminated. However, if a thicker film is desired, the entire four-step process may be repeated. By alternating the provision of the tungsten diazabutadiene compound, second precursor, and reaction gas, a film of desired composition and thickness can be deposited.

When the reaction gas in this exemplary ALD process is treated with a plasma, the exemplary ALD process becomes an exemplary PEALD process. The reaction gas may be treated with plasma prior or subsequent to introduction into the chamber.

The tungsten-containing films resulting from the processes discussed above may include a pure tungsten (W), tungsten nitride (WN), tungsten carbide (WC), tungsten carbonitride (WCN), tungsten silicide (WₖSiₗ), or tungsten oxide (WₙOₘ) film, wherein k, l, m, and n are integers which inclusively range from 1 to 6. One of ordinary skill in the art will recognize that by judicial selection of the appropriate tungsten diazabutadiene compound, optional second precursors, and reaction gas species, the desired film composition may be obtained.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the tungsten-containing film may be exposed to a temperature ranging from approximately 200° C. and approximately 1000° C. for a time ranging from approximately 0.1 second to approximately 7200 seconds under an Inert atmosphere, a H-containing atmosphere, a N-containing atmosphere, an O-containing atmosphere, or combinations thereof. Most preferably, the temperature is 400° C. for 3600 seconds under a H-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, may reduce carbon and nitrogen contamination of the tungsten-containing film. This in turn tends to improve the resistivity of the film.

After annealing, the tungsten-containing films deposited by any of the disclosed processes may have a bulk resistivity at room temperature of approximately 5.5 μohm·cm to approximately 70 μohm·cm, preferably approximately 5.5 μohm·cm to approximately 20 μohm·cm, and more preferably approximately 5.5 μohm·cm to approximately 12 μohm·cm. Room temperature is approximately 20° C. to approximately 28° C. depending on the season. Bulk resistivity is also known as volume resistivity. One of ordinary skill in the art will recognize that the bulk resistivity is measured at room temperature on W films that are typically approximately 50 nm thick. The bulk resistivity typically increases for thinner films due to changes in the electron transport mechanism. The bulk resistivity also increases at higher temperatures.

### EXAMPLES

The following non-limiting examples are provided to further illustrate embodiments of the invention. However, the examples are not intended to be all inclusive and are not intended to limit the scope of the inventions described herein.

### Example 1

### Synthesis of W(iPrN-CH═CH—NiPr)₃

In a 100 mL schlenk flask under nitrogen, 1.01 g (7.2 mmol) of glyoxal-bis(isopropylimin) was introduced with 10 mL of anhydrous THF. Three equivalents of freshly cut lithium metal 150 mg (21.6 mmol) were added at room temperature and allowed to react overnight. The solution turned dark red. Excess metal lithium was removed by filtration. This solution was slowly added dropwise to a suspension of WCl₆ 952 mg (2.4 mmol) in THF at −78° C. The dark solution was allowed to stir overnight at room temperature. Solvent was then removed under vacuum and the precursor dissolved in pentane. Filtration over Celite brand diatomaceous earth followed by evaporation of the pentane under vacuum was performed to give a waxy solid. Due to the sticky nature of the raw material, volatile impurities are removed using a distillation elbow. Subsequent sublimation at 150° C.@300 mTorr yielded dark crystals 225 mg (15% yield) which NMR¹H shifts correspond to the structure of W^{(+VI)}(iPrN-CH═CH—NiPr)₃. NMR¹H(C₆D₆, delta): 6.61 ppm (s, 2H), 4.50 ppm 26 (m, 2H), 1.27 (d, 6H), 1.0 (d, 6H).

### Example 2

### Thermal Characterization of W(iPrN-CH═CH—NiPr)₃

The thermal properties of the molecule synthesized in Example 1 were evaluated using a thermo-gravimetry tool placed in inert atmosphere. As shown in the FIGURE, the amount of residue was 4% under vacuum conditions, whereas it was close to 20% in standard conditions (e.g., atmospheric conditions) (the atmospheric ThermoGravimetric Analysis (TGA) and atmospheric Differential Thermal Analysis (DTA) results are shown by the solid line, the vacuum TGA and vacuum DTA results are shown by the dashed lines, with the TGA results starting in the upper left portion of the graph and proceeding towards the bottom right and the DTA results starting on the left in the middle of the graph). These results prove that 1—the purity of the molecule was good (low residual amount in vacuum mode), and; 2—the higher residual amount in standard conditions means that the molecule started to decompose from around 300° C., proving that temperature window of the deposition process could start from a temperature much lower than 300° C.

### Example 3

### Prophetic Deposition of Thin W Films Using W(iPrN-CH═CH—NiPr)₃

W(iPrN-CH═CH—NiPr)₃ was synthesized as described in Example 1. It is expected to obtain W films using this molecule and the following example describes one way, among others, to deposit such films.

The tungsten molecule will be placed in a canister. Vapors of W(iPrN-CH═CH—NiPr)₃ will be transported to the reaction furnace by flowing nitrogen within the heated canister in order to provide enough vapor. Hydrogen will be introduced into the deposition system to react with the tungsten vapors at the surface of the wafer in an ALD scheme (introduction of precursors' vapors separated by sufficiently long inert gas purges). Hydrogen (H₂) is believed to be a molecule of choice, but any type of reducing agent may be selected. W films will be obtained. Analytical results will show that a saturation mode typical to ALD mode is obtained when extending the introduction time of the vapors of the tungsten molecule.

### Example 4

### Alternative Synthesis of W(iPrN-CH═CH—NiPrb)₃

2 g of WCl₄ (6 mmol), THF (30 mL) and 0.86 g of iPr-DAD (6 mmol) are added to a 100 mL schlenk flask (the “First Flask”) under nitrogen and the reaction mixture is allowed to react for 12 hours. 1.72 g of iPr-DAD (12.2 mmol) was dissolved in THF (30 mL) in a second 100 mL schenk flask (the “Second Flask”). 0.26 g of Li wire (37 mmol) was slowly added to the solution. After 12 hours at room temperature, the excess Li was removed. The resulting dark burgundy solution in the Second Flask was transferred to the First Flask. The resulting mixture in the First Flask was allowed to react at room temperature for one day and produced a dark violet solution. The dark violet solution was evaporated, extracted with pentane and filtered through Celite brand diatomaceous earth. Due to the sticky nature of the raw material, volatile impurities are removed using a distillation elbow. The resulting waxy solid was purified by sublimation (165° C.-600 mTorr) to yield as dark violet solid (1.1 g or 28% w/w). NMR¹H (C₆D₆, delta): 6.61 ppm (s, C═CH), 4.48 ppm (se, CH(CH₃)₂), 1.27 (d, CH(CH₃)₂), 1.00 (d, CH(CH₃)₂).

The ¹H-NMR of the W(DAD)₃ produced in Example 4 contained less Impurities than the ¹H-NMR of the W(DAD)₃ produced in Example 1. Similarly, the residual amount in TGA is higher in Example 1 than in Example 4. The molecule exhibits a vapor pressure of 195° C. at 1 torr, approximately 5% residue in vacuum TGA, and approximately 17% residue in atmospheric TGA.

### Example 5

### Synthesis of W(nPrN-CH═CH-NnPr)₃

W(nPrN-CH═CH-NnPr)₃ was synthesized in a manner similar to that of Example 1. The liquid produced was difficult to purify by distillation. Applicants believe that adjusting the reaction time and reactant properties may yield product better capable of being purified. The W(nPr-DAD)3 molecule exhibited good thermal properties, having a vapor pressure of 135° C. at 1 torr, approximately 4% residue in vacuum TGA, and approximately 5% residue in atmospheric TGA.

### Example 6

### Synthesis of Other W(DAD)₃ Molecules

Synthesis of W(DAD)₃ molecules wherein R₁ and R₂ were tBu and R₃ and R₄ were H; R₁ and R₂ were iPr, R₃ was Me, and R₄ was H; and R₁ and R₂ were Me and R₃ and R₄ were Me; and R₁ and R₂ were iPr and R₃ and R₄ were M failed using the method of Example 1. Synthesis by the other methods has not yet been conducted.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

1. A molecule having the formula W(R₁—N═CR₃—CR₄═N—R₂)₃, wherein each of R₁, R₂, R₃ and R₄ is independently selected from the group consisting of H; a C1-C6 linear, branched, or cyclic alkyl group; a C1-C6 linear, branched, or cyclic alkylsilyl group; a C1-C6 linear, branched, or cyclic alkylamino group; and a C1-C6 linear, branched, or cyclic fluoroalkyl group.

2. The molecule of claim 1, wherein each of R₁, R₂, R₃ and R₄ is independently selected from the group consisting of H and a C1-C6 linear, branched, or cyclic alkyl group.

3. The molecule of claim 2, wherein R₁ and R₂ are independently selected from the group consisting of Me, Et, nPr, iPr, nBu, tBu, and iBu and R₃ and R₄ are independently selected from H or Me.

4. The molecule of claim 1, wherein the molecule is W(nPrN═CH—CH=NnPr)₃ or W(iPrN═CH—CH=NiPr)₃.

5. A method of depositing a tungsten containing film, the method comprising:
introducing at least one tungsten diazabutadiene compound into a reactor having at least one substrate disposed therein, the at least one tungsten diazabutadiene compound having the formula W(R₁—N═CR₃—CR₄═N—R₂)₃, wherein each of R₁, R₂, R₃ and R₄ is independently selected from the group consisting of H; a C1-C6 linear, branched, or cyclic alkyl group; a C1-C6 linear, branched, or cyclic alkylsilyl group; a C1-C6 linear, branched, or cyclic alkylamino group; and a C1-C6 linear, branched, or cyclic fluoroalkyl group; and
depositing at least part of the tungsten diazabutadiene compound onto the at least one substrate to form the tungsten containing film.

6. The method of claim 5, wherein the tungsten diazabutadiene compound is W(nPrN═CH—CH=NnPr)₃ or W(iPrN═CH—CH=NiPr)₃.

7. The method of claim 5, wherein the method is performed at a temperature between about 20° C. and about 600° C., preferably between about 100° C. and about 400° C.

8. The method of claim 5, wherein the method is performed at a pressure between about 0.1 Pa and about 10⁵ Pa, preferably between about 2.5 Pa and about 10³ Pa.

9. The method of claim 5, wherein the method is selected from the group consisting of chemical vapor deposition (CVD), atomic layer deposition (ALD), plasma CVD, plasma ALD, pulse CVD, low pressure CVD, sub-atmospheric CVD, atmospheric pressure CVD, hot-wire CVD, hot-wire ALD, and super critical fluid deposition.

10. The method of claim 5, wherein the tungsten containing film is selected from the group consisting of tungsten (W), tungsten silicide (WSi), tungsten nitride (WN), tungsten carbide (WC), tungsten carbonitride (WNC), and tungsten oxide (WO).

11. The method of claim 5, further comprising:
introducing a reaction gas into the reactor at the same time or at an alternate time as the introduction of the tungsten diazabutadiene molecule.

12. The method of claim 11, wherein the reaction gas is a reducing agent.

13. The method of claim 12, wherein the reducing agent is selected from the group consisting of: N₂, H₂; SiH₄; Si₂H₆; Si₃H₈; NH₃; (CH₃)₂SiH₂; (C₂H₅)₂SiH₂; (CH₃)SiH₃; (C₂H₅)SiH₃; phenyl silane; N₂H₄; N(SiH₃)₃; N(CH₃)H₂; N(C₂H₅)H₂; N(CH₃)₂H; N(C₂H₅)₂H; N(CH₃)₃; N(C₂H₅)₃; (SiMe₃)₂NH; (CH₃)HNNH₂; (CH₃)₂NNH₂; phenyl hydrazine; B₂H₆; 9-borabicyclo[3,3,1]nonane; dihydrobenzenfuran; pyrazoline; trimethylaluminium; dimethylzinc; diethylzinc; radical species thereof; and mixtures thereof.

14. The method of claim 11, wherein the reaction gas is an oxidizing agent.

15. The method of claim 14, wherein the oxidizing agent is selected from the group consisting of: O₂; O₃; H₂O; H₂O₂.
